(19) United States
(12) Patent Application Publication
(10) Pub. No.: US 2005/0044460 A1
(43) Pub. Date: Feb. 24, 2005

(54) Mapping test mux structure

(76) Inventors: Timothy E. Hoglund, Colorado Springs, CO (US); Coralyn S. Gauvin, Colorado Springs, CO (US)

Correspondence Address: LSI Logic Corporation;Corporate Legal Department, M/S D-106, Intellectual Property Services Group, 1551 McCarthy Boulevard, Milpitas, CA, 95035, US

(21) Appl. No.: 10/646,010

(22) Filed: Aug. 22, 2003

(51) Int. Cl. G01R 31/28

(52) U.S. Cl. 714/724

(57) ABSTRACT

A method and apparatus for observing the state of signals during chip testing. For a chip containing many instances of the same module, it is advantageous to observe the same signal set for several of the modules concurrently. In particular, the present invention improves upon prior test MUX methods by placing additional mapping/steering logic within a module to provide greater flexibility in selecting signal sets for concurrent observation. The addition of mapping/steering logic to a module's test MUX structure allows a chip designer to arbitrarily map each of the test signal groups to any of the test output groups.

### BACKGROUND OF THE INVENTION

1. Technical Field

The present invention is directed generally toward chip testing. Specifically, the invention relates to a method and apparatus for concurrently observing the state of internal signals within a chip during testing.

2. Description of the Related Art

Since the introduction of integrated circuitry some decades ago, integrated circuit technology has progressed steadily to provide continually increasing integrated circuit density and speed, while lowering power consumption. As a result, extremely complex integrated circuit designs have become possible, sometimes including up to millions of transistors. There is no indication that this trend towards higher density and speed in integrated circuits will abate, or reverse, at any time in the foreseeable future.

As the ability to increase logic capacity or density of modern integrated circuitry has grown, so has the complexity of modern logic designs. Associated with such increased logic complexity and logic density, however, is a similar increase in interconnection density (i.e., the interconnections between logic elements on an integrated circuit chip). Generally, the greater the number of logic elements which are employed in a logic design, the greater the number of logic signals which interconnect them. These interconnections can often occupy large areas on an integrated circuit die or semiconductor die, particularly when large busses and complex logic blocks are employed in the design of the integrated circuit.

In attempting to improve interconnection efficiency, designers will often employ multiplexing (MUX) techniques. As is known, communication signals from several channels may be combined in a multiplexer and sent in the form of a single, complex signal to another device that recovers the separate signals at the receiving end. FIG. 1 is representative of this technique.

FIG. 1 is a block diagram of a multiplexed circuit 100a known in the art. Three logic blocks 110a (logic block #1), 110b (logic block #2), and 110c (logic block #3) are interconnected via multiplexer (MUX) 120. Well known in principle to those of ordinary skill in the art, multiplexer 120 may combine selected “n” input signals on line 115a with selected “m” input signals on line 115b based upon the state of a selection signal (not shown). Multiplexer 120 presents selected signals onto a single signal wire, “k” output line 115c, to block 110c, where “k” , “m”, and “n” refer to a number of signals being carried on lines 115c, 115b and 115a, respectively. By the use of multiplexer 120, logic block #3 110c can be caused to receive selected signals from logic block #1 110a and logic block #2 110b, at any given time.

Due to the growing complexity of modern logic designs, the reliability of data signals in the integrated circuit chips is an ever-increasing important issue. Prior to employing test MUX methodology, testing strategy consisted of simulating the functionality of the chips as best as possible and then bringing a few state machines and other variables that were of particular concern or interest out to registers. However, the observable signals, such as external pins and the couple of registers that could be read, were a very small percentage of signals in the chip. Thus, designers still faced a large amount of guesswork when it came to debugging the chips. As a consequence of the testing limitations, debug cycles spanned several chip revisions, resulting in a time-consuming and costly process.

The addition of a single large MUX structure to the chip design improved the ability to observe the state of internal signals during operation. The MUX structure allowed the designers to select signals from any area of the chip and output to a few general purpose pins. This single large test MUX structure offered great flexibility in selecting signal sets for observation by providing for any-to-any observability. Debugging chips became faster and easier. However, despite providing the advantage of allowing one to “mix and match” signal sets, the single large MUX approach also presented substantial interconnect routing costs and congestion. Physical placement became a problem, since there were thousands of wires being routed from all over the chip to basically a single place. Consequently, in order to get a routable database, some of the observable signals had to be discarded, thereby discarding some of the destination routing flexibility.

To address the interconnect routing liability of the single large MUX approach, a hierarchy-based test MUX was designed. The hierarchy-based test MUX relieved the congestion by distributing the routing destinations throughout the chip and increased the capability to observe more signals than using the single large MUX structure. However, the destination flexibility was now removed, and signal observation was limited to a single group together. As a result, although the hierarchy-based test MUX assisted in validation/debug efforts, constraints were placed upon which signals could be concurrently observed.

Consequently, it would be beneficial to have a test MUX structure that provides greater flexibility in selecting signals for concurrent observation. Furthermore, it would also be desirable to have a test MUX structure that allowed for observing the same signal set for several modules concurrently. Moreover, it would be desirable to have a test MUX structure that allowed the mapping of each of the test signal groups to any of the test output groups.

### SUMMARY OF THE INVENTION

The present invention provides a method and apparatus for observing the state of signals during chip testing. For a chip containing many instances of the same module, it is advantageous to observe the same signal set for several of the modules concurrently. In particular, the present invention improves upon prior test MUX methods by placing additional mapping/steering logic within a module to provide greater flexibility in selecting signal sets for concurrent observation. The addition of mapping/steering logic to a module's test MUX structure allows a chip designer to arbitrarily map each of the test signal groups to any of the test output groups.

### BRIEF DESCRIPTION OF THE DRAWINGS

The novel features believed characteristic of the invention are set forth in the appended claims. The invention itself however, as well as a preferred mode of use, further objects and advantages thereof, will best be understood by reference to the following detailed description of an illustrative embodiment when read in conjunction with the accompanying drawings, wherein:

FIG. 1 shows a block diagram of a prior art circuit employing a multiplexer;

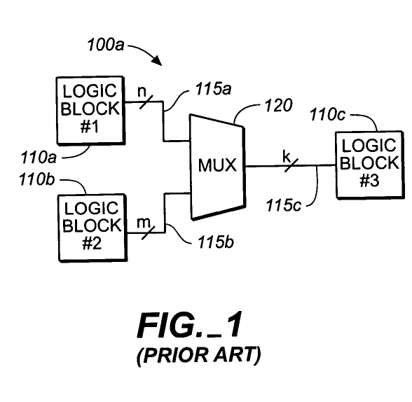

FIG. 2 shows a block diagram of a module level test MUX structure with mapping/steering logic in accordance with the present invention;

FIG. 3 shows a block diagram of a top level test MUX structure in accordance with the present invention;

FIG. 4 shows a flowchart illustrating a process in the logical design in accordance with the present invention; and

FIG. 5 shows a block diagram of the mapping logic in accordance with the present invention.

### DETAILED DESCRIPTION

The description of the preferred embodiment of the present invention has been presented for purposes of illustration and description, but is not intended to be exhaustive or limited to the invention in the form disclosed. Many modifications and variations will be apparent to those of ordinary skill in the art. The embodiment was chosen and described in order to best explain the principles of the invention the practical application to enable others of ordinary skill in the art to understand the invention for various embodiments with various modifications as are suited to the particular use contemplated.

As previously mentioned, the present invention provides a method and apparatus for observing the state of signals during chip testing. The present invention places additional mapping/steering logic within a module to provide greater flexibility in selecting signal sets for concurrent observation. The addition of mapping/steering logic to a module's test MUX structure allows a chip designer to arbitrarily map each of the test signal groups to any of the test output groups.

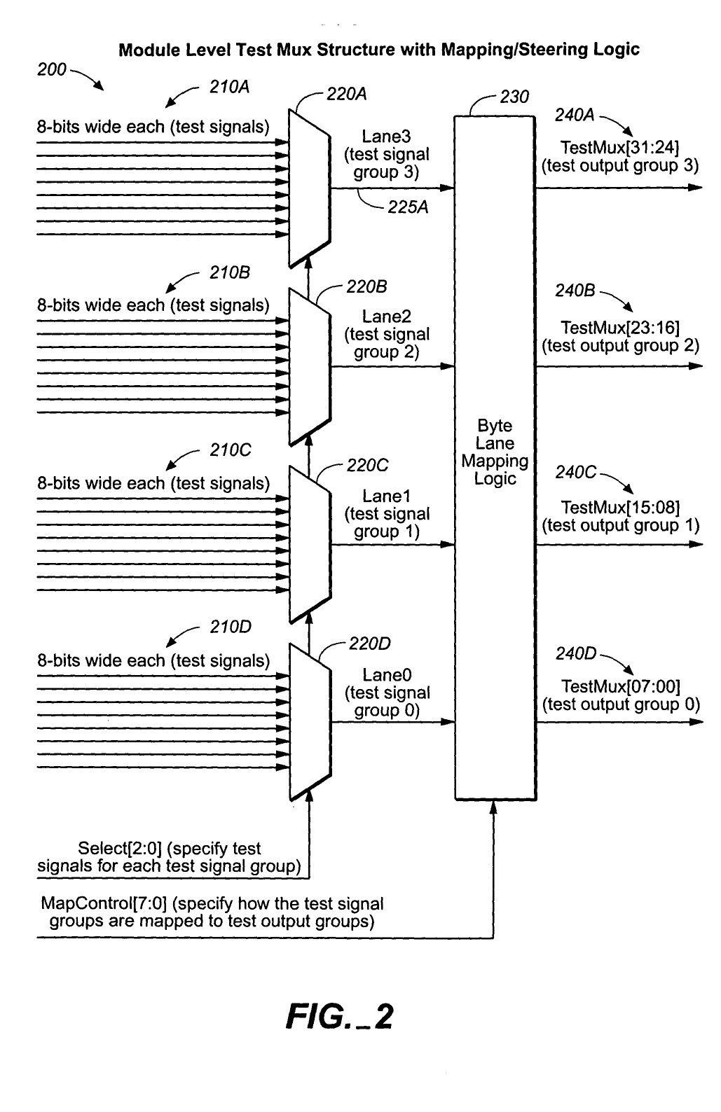

For a chip containing many instances of the same module, it is advantageous to observe the same signal set for several of the modules concurrently. The present invention improves upon prior test MUX methods by placing additional mapping/steering logic within a module, as shown in FIG. 2. The addition of mapping/steering logic to a module's test MUX structure provides greater flexibility in selecting signal sets for concurrent observation and allows for mapping each of the test signal groups to any of the test output groups.

FIG. 2 shows a block diagram of a module level test MUX structure in accordance with the present invention. Proposed test MUX structure 200 of the present invention improves upon conventional test MUX processes by placing mapping logic 230 within the module. Mapping logic 230 is applied to the output of multiplexers 220A, 220B, 220C, and 220D. As a result, the present invention enhances the hierarchical test MUX method through the addition of mapping/steering logic to the test MUX structure within the module to allow for mapping each of the test signal groups from the multiplexers to any of the test output groups.

For example purposes, a 32-bit test MUX is used in the chip design shown in FIG. 2. Module level test MUX structure 200 inputs 8-bit wide test signals 210A, 210B, 210C, and 210D to multiplexers 220A, 220B, 220C, and 220D, respectively. For example, test signals 210A are received at multiplexer 220A. Multiplexer 220A then specifies which signals from test signals 210A are to be included in test signal group 3 225A. Selected signals from test signals 210A are combined to create a single output in the form of test signal group 3 225A. Test signal group 3 225A is then mapped to any of test output groups 240A, 240B, 240C, or 240D.

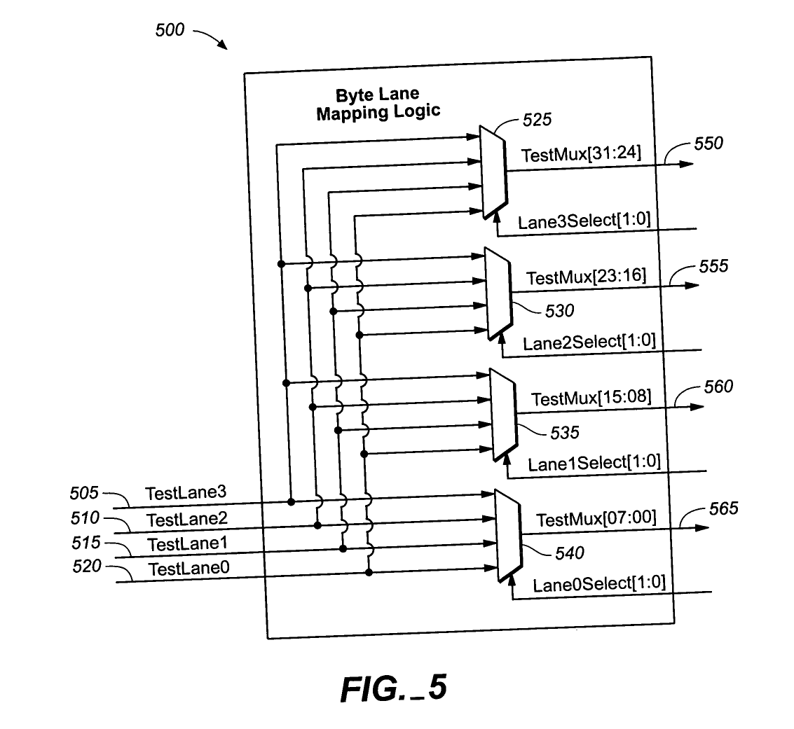

FIG. 5 illustrates the mapping process shown in FIG. 2. Byte lane mapping logic specifies how the test signal groups output from the module are mapped to the test output groups. For example, test signal group 3 505, test signal group 2 515, test signal group 1 520, and test signal group 0 525 are output from multiplexers 220A, 220B, 220C, and 220D in FIG. 2. Each test signal group may then be mapped to any of the test output groups (550, 555, 560, and 565).

Prior art test MUX methods that offered any-to-any (unconstrained) observability resulted in substantial interconnect routing costs and congestion. Subsequent prior art test MUX methods that attempted to reduce the routing costs and congestion resulted in a constrained but fixed mapping of the test MUX signals. In contrast, the addition of the byte lane mapping logic in the present invention as shown in FIG. 2 and FIG. 5 offers a constrained but flexible mapping of test MUX signals to test MUX output. Flexible mapping allows a chip designer to move the test outputs around in order to observe the same set of signals from two or more similar or identical blocks at the same time.

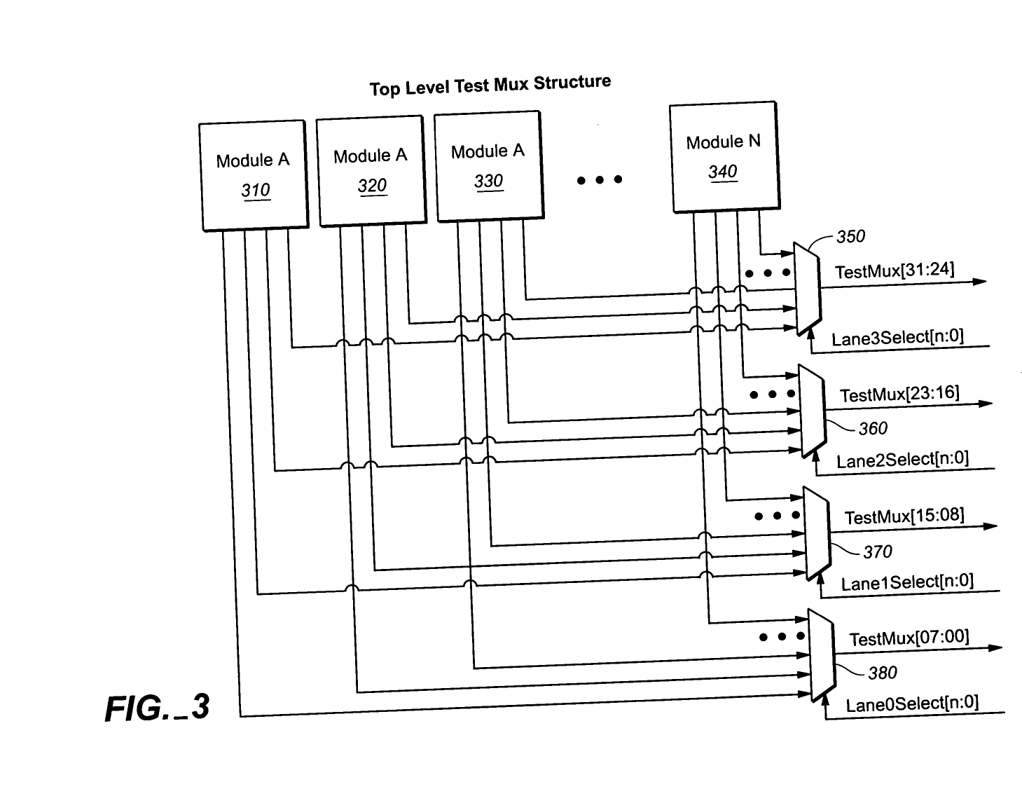

As mentioned previously, the present invention involves chip testing by observing the state of internal signals during operation. The present invention may also be implemented in multiple modules, allowing observation of the same signal set for several modules concurrently. FIG. 3 illustrates how the invention as described in FIG. 2 is expandable. FIG. 3 shows a top-level test MUX structure having a plurality of modules 310, 320, 330, and 340. Although only modules 310, 320, 330, and 340 are shown, additional modules may be added. Each module may be different from the other modules, or there may be multiple copies of the same module in the chip design. Since there may be multiple copies of the very same module in the device, the flexibility of moving the test outputs around is needed in order to observe the same type of signals from two similar modules at the same time.

The plurality of modules 310, 320, 330, and 340 in the top-level test MUX structure in FIG. 3 perform the MUXing process as described in FIG. 2 to create test signal groups. The byte lane mapping logic, as illustrated by multiplexers 350, 360, 370, and 380, is applied to the test signal groups. For example, module 310 provides test signal groups to multiplexers 350, 360, 370, and 380. Modules 320, 330, and 340 also provide test signal groups to multiplexers 350, 360, 370, and 380. Mapping logic in multiplexers 350, 360, 370, and 380 then specify which test group signals from each module are to be included in each test output group. Selected test group signals are combined to create a single test output group, as described above in FIG. 2 and FIG. 5.

The present invention as illustrated in FIG. 3 remains applicable even as the width of buses and the number of test output groups scale according to individual chip requirements. In other words, the uses for the present invention are only limited by the individual chip requirements. Each module will perform the test MUX method and allow for mapping each of the test signal groups to any of the test output groups of the present invention.

Thus, the present invention provides a mechanism for chip testing by concurrently observing the state of internal signals during operation. With the present invention, the addition of mapping/steering logic within the module allows each of the test signal groups to be arbitrarily mapped to any of the test output groups, thereby providing the flexibility of moving the test outputs around in order to observe the same set of signals from two or more similar or identical blocks at the same time.

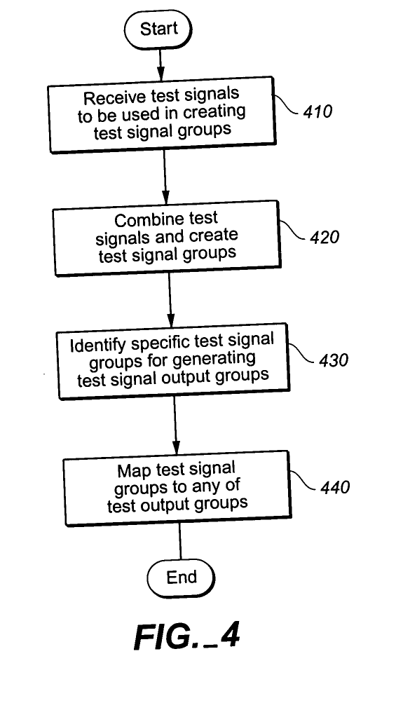

FIG. 4 is a flowchart outlining an exemplary operation of the present invention. As shown in FIG. 4, the test MUX method starts with receiving test signals in the module to be used in creating test signal groups (step 410). For each set of test signals, a multiplexer is used to combine the test signals and create the single data signal, or a test signal group (step 420). Once the aggregate test signals have been multiplexed or combined into test signal groups, specific test signal groups are identified to be used in generating test signal output groups (step 430). Mapping or steering logic is performed on each test signal group, whereby the test signal groups are mapped to any of the test output groups (step 440).

Thus, the present invention solves the disadvantages of the prior art by providing a method and apparatus for concurrently observing the state of signals during chip testing. It is critical that designs be verified for functional correctness at every stage in the design flow in order to ensure that errors are detected as early as possible. Early detection of errors may prevent massive redesigning efforts from occurring well into the design process. It is advantageous for a chip containing many instances of the same module to observe the same signal set for several of the modules concurrently. The present invention enhances the hierarchical test MUX method by disclosing a test MUX structure which allows for greater flexibility in selecting signals for concurrent observation. The addition of mapping/steering logic to a module's test MUX structure allows a chip designer to arbitrarily map each of the test signal groups to any of the test output groups.

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated.

1. A method for observing the state of internal signals during chip testing, comprising:
receiving specific test signals in at least one module in order to form a plurality of test signal groups;
combining the specific test signals received for each test signal group to create the plurality of test signal groups;
identifying specific test signal groups in order to form a plurality of test signal output groups; and
mapping the specific test signal groups identified for each test signal output group to create the plurality of test signal output groups.

2. The method of claim 1 wherein the at least one module includes a plurality of modules.

3. The method of claim 2, further comprising:
concurrently observing test signals for a plurality of modules.

4. The method of claim 3 wherein the plurality of modules includes identical modules.

5. The method of claim 1 wherein combining the specific test signals received for each test signal group to create the plurality of test signal groups is performed by a multiplexer.

6. The method of claim 1 wherein mapping the specific test signal groups identified for each test signal output group to create the plurality of test signal output groups is performed using byte lane mapping logic.

7. An apparatus for observing the state of internal signals during chip testing, comprising:
multiplexing means for combining test signals in a module to create specified test signal groups;
mapping means for mapping specified test signal groups to specified test output groups.

8. A system for observing the state of internal signals during chip testing, comprising:
means for receiving specific test signals in at least one module in order to form a plurality of test signal groups;
means for combining the specific test signals received for each test signal group to create the plurality of test signal groups;
means for identifying specific test signal groups in order to form a plurality of test signal output groups; and
means for mapping the specific test signal groups identified for each test signal output group to create the plurality of test signal output groups.

9. The system of claim 8 wherein the at least one module includes a plurality of modules.

10. The system of claim 9, further comprising:
concurrently observing test signals for a plurality of modules.

11. The system of claim 10 wherein the plurality of modules includes identical modules.

12. The system of claim 8 wherein the means for combining the specific test signals received for each test signal group to create the plurality of test signal groups is a multiplexer.

13. The system of claim 8 wherein the means for mapping the specific test signal groups identified for each test signal output group to create the plurality of test signal output groups is performed using byte lane mapping logic.
